(19) United States
(12) Patent Application Publication
(10) Pub. No.: US 2010/0012037 A1
(43) Pub. Date: Jan. 21, 2010

(54) SUBSTRATE TRANSFER APPARATUS

(76) Inventors: Katsushi Kishimoto, Osaka (JP); Yusuke Fukuoka, Osaka (JP); Mitsuhiro Toyoda, Osaka (JP); Hiroyuki Tadokoro, Osaka (JP); Yusuke Ozaki, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/503,167

(22) Filed: Jul. 15, 2009

(30) Foreign Application Priority Data
Jul. 16, 2008 (JP) 2008-184831

(51) Int. Cl. C23C 16/54; C23C 16/513

(52) U.S. Cl. 118/729

(57) ABSTRACT

A substrate transfer apparatus comprising: a plurality of floating-transfer guide plates adjacent to each other with a space, each of guide plate having a plurality of floating gas ejecting holes; a gas supplying source for supplying a floating gas to the guide plates; a tray that is placed on one of the guide plates in order to mount a substrate to be transferred, and that is floated by the floating gas; and a transfer arm for transferring the floated tray to the adjacent other guide plate from the guide plate, wherein the tray includes a main body portion having both side edges parallel to a transfer direction of the tray, and an outward projecting portion that is formed so as to partially project outwardly from at least one of both side edges of the main body portion, and wherein the transfer arm is in contact and engaged with the outward projecting portion when the tray is transferred by the transfer arm.

### CROSS-REFERENCE TO RELATED APPLICATION

This application is related to Japanese patent application No. 2008-184831 filed on Jul. 16, 2008 whose priority is claimed under 35 USC §119, the disclosure of which is incorporated by reference in its entirety.

### BACKGROUND OF THE INVENTION

1. Field of the Invention

The present invention relates to a substrate transfer apparatus, and more particularly to a substrate transfer apparatus that transfers a substrate in order to perform, for example, a plasma process onto a surface of the substrate, which is a plate-like subject to be processed having a flat plate shape.

2. Description of the Related Art

When a semiconductor thin film is formed on a surface of a substrate that is a subject to be processed having a flat plate shape, a plasma processing apparatus employing a plurality of vacuum chambers has widely been used. In the plasma processing apparatus described above, at least one of the plurality of vacuum chambers is generally specified as the vacuum chamber for a plasma process for performing the plasma process onto the surface of the substrate. Further, the plasma processing apparatus generally includes a transfer apparatus for transferring the substrate among the plurality of vacuum chambers.

As the transfer apparatus, there has been known an apparatus of a floating-type transfer system. In the apparatus of the floating-type transfer system, a guide plate for mounting a substrate is provided to each of vacuum chambers, and the substrate is mounted on the guide plate. Then, the substrate is floated from the guide plate by means of a floating gas in the vacuum chamber. The floated substrate is transferred to the adjacent vacuum chamber along the guide plate.

Specifically, the substrate transfer apparatus of the floating-type transfer system includes a floating-transfer guide plate provided at each vacuum chamber and provided with a plurality of floating-gas ejecting holes, and a gas supplying source for supplying the floating gas to the respective guide plates. Since the floating gas is ejected from the gas ejecting holes of the guide plate, the substrate is floated from the guide plate, and then, the floated substrate is transferred along the guide plate among the plurality of vacuum chambers due to external force.

Apparatuses disclosed in Japanese Unexamined Utility Model Publication No. 61-178725 and Japanese Unexamined Patent Publication No. 7-228342 have been also known, for example, as the substrate transfer apparatus utilizing the transfer system described above.

The substrate transfer apparatus of the floating transfer system described above includes, for example, a horizontally extending transfer arm that can move up and down for transferring a rectangular substrate among a plurality of vacuum chambers, and a transfer drive unit for transferring/moving up/down the transfer arm in a transfer direction and in a vertical direction.

However, there arise problems described below in the substrate transfer apparatus, of the substrate transfer apparatuses having the transfer arm and the transfer drive unit, in which the substrate is not directly mounted on the guide plate, but the substrate is mounted through a tray placed on the guide plate in order to protect the surface of the substrate.

The tray has to be formed to have an area larger than the area of the substrate to be mounted thereon. In order to achieve this, the tray generally has a rectangular planar shape, and a portion close to a side edge and a portion close to an end edge are formed to project, whereby the length of the long side and the length of the short side are larger than those of the substrate. The reason is because it is necessary to form a plurality of fitting holes along the transfer direction, with which a suspending leading portion of the transfer arm is releasably fitted by an ascending/descending movement, at the portions close to the side edge of the tray on which the substrate is mounted.

When the tray and the transfer arm are configured as described above, it is not so easy to achieve positioning of the fitting holes on the tray and the leading portion of the transfer arm upon the fitting. This provides non-smooth fitting, which entails a trouble related to the transfer.

When the tray and the transfer arm are configured as described above, and further, the guide plate has incorporated therein a heater for heating the substrate, wherein the heater is formed to have the width almost the same as that of the substrate, the problem described below arises. Specifically, because the portion close to the side edge of the tray projects from the side edge of the guide plate, the difference in a temperature distribution occurs between a portion of the tray facing the heater and a portion of the tray projecting from the heater, when the substrate is heated by the heater. Due to the difference in the temperature distribution, the tray might be curved upwardly at the portion close to the side edge, which entails a trouble related to the transfer.

### SUMMARY OF THE INVENTION

The present invention is accomplished in view of the foregoing circumstances, and aims to provide a substrate transfer apparatus that can prevent the possibility of the trouble related to the transfer.

According to the present invention, there is provided that a substrate transfer apparatus comprising:

a plurality of floating-transfer guide plates adjacent to each other with a space, each of guide plate having a plurality of floating gas ejecting holes;

a gas supplying source for supplying a floating gas to the guide plates;

a tray that is placed on one of the guide plates in order to mount a substrate to be transferred, and that is floated by the floating gas; and

a transfer arm for transferring the floated tray to the adjacent other guide plate from the guide plate, wherein

the tray includes a main body portion having both side edges parallel to a transfer direction of the tray, and an outward projecting portion that is formed so as to partially project outwardly from at least one of both side edges of the main body portion,

and wherein the transfer arm is in contact and engaged with the outward projecting portion when the tray is transferred by the transfer arm.

### BRIEF DESCRIPTION OF THE DRAWINGS

FIG. 1 is a partially cutout perspective view showing a substrate transfer apparatus, which is incorporated in a plasma processing apparatus, according to a first embodiment of the present invention;

FIG. 2 is a view for explaining the configuration of the substrate transfer apparatus shown in FIG. 1;

FIG. 3 is a plan view of a tray, which is one component in the substrate transfer apparatus shown in FIG. 1;

FIG. 4 is a plan view of a transfer arm, which is another component in the substrate transfer apparatus shown in FIG. 1;

FIG. 5 is a plan view of a tray, which is one component of a substrate transfer apparatus that is incorporated in a plasma processing apparatus according to a second embodiment of the present invention;

FIG. 6 is a perspective view of an arm portion of a transfer arm, which is another component of the substrate transfer apparatus according to the second embodiment of the present invention;

FIG. 7 is a perspective view of an arm portion of the transfer arm shown in FIG. 6 according to a first modification;

FIG. 8 is a perspective view of an arm portion of the transfer arm shown in FIG. 6 according to a second modification;

FIG. 9 is a perspective view of an arm portion of the transfer arm shown in FIG. 6 according to a third modification;

FIG. 10 is a partially cutout perspective view showing a substrate transfer apparatus, which is incorporated in a plasma processing apparatus, according to a third embodiment of the present invention;

FIG. 11 is a plan view of a tray, which is one component in the substrate transfer apparatus shown in FIG. 10;

FIG. 12 is a cutout enlarged plan view of the tray shown in FIG. 11 in a first modification; and

FIG. 13 is a cutout enlarged plan view of the tray shown in FIG. 11 in a second modification.

### DETAILED DESCRIPTION OF THE PREFERRED EMBODIMENTS

According to one aspect of the present invention, the substrate transfer apparatus further comprises a rail provided to be parallel to the transfer direction, wherein the transfer arm includes a base portion that can horizontally reciprocate along the rail, a guide portion provided at the base portion so as to be capable of horizontally reciprocating in the direction orthogonal to the transfer direction, and an arm portion that is provided horizontally at the guide portion in the direction parallel to the transfer direction and positioned at a side of the placed tray, and that has an inward projecting end, which is a free end, wherein the inward projecting end of the transfer arm is in contact and engaged with and disengaged from the outward projecting portion of the tray when the guide portion of the transfer arm reciprocates.

The plurality of floating-transfer guide plates in the substrate transfer apparatus is arranged so as to be spaced from each other. Examples of the guide plates include the one provided with the plurality of floating-gas ejecting holes, and used to transfer a floated plate-like subject to be processed—the tray placed on the guide plate and a plasma-processing substrate mounted on the tray—by external force. There is no limitation on the shape and material thereof.

Each of the guide plates is made of, for example, a rectangular plate member having a floating-gas supplying tube connected to an external gas supplying source. The guide plates are arranged on one line along the transfer direction in a plurality of processing chambers adjacent to each other via a gate valve. A floating gas is supplied to each of the guide plates from the gas supplying source. Any gases can be used as the floating gas, so long as they do not give damages to the guide plates and the subject to be processed. Preferable examples of the floating gas include nitrogen gas, helium gas, argon gas, etc.

The plurality of (e.g., 100 to 200) floating-gas ejecting holes (e.g., circular holes each having a diameter of 0.5 to 5.0 mm) on the respective guide plates can be composed of, for example, a plurality of independent ejecting hole groups (e.g., 5 to 10 groups). The ejecting hole groups are formed transversely in the transfer direction and formed with a predetermined space in the transfer direction.

There is no limitation on the shape and material of the tray on which the substrate is to be mounted, so long as it can be mounted on the guide plate as having the substrate mounted thereon, and can endure the temperature and pressure in various processes. It is preferable that the tray is light in weight from the viewpoint of being floated by the floating gas. For example, the tray may be made of a thin plate (having a thickness of 0.5 mm to 2.0 mm, for example) of stainless steel or an aluminum alloy.

The transfer arm is for transferring the floated tray to the adjacent other guide plate from the guide plate.

The tray has a main body portion and a projecting portion. The main body portion has both side edges parallel to the transfer direction. The projecting portion is formed so as to partially project outwardly from at least one of the both side edges at the main body portion. The projecting portion is in contact with and engaged with the transfer arm when the tray is transferred by the transfer arm.

The transfer arm has a base portion, a guide portion, and an arm portion. The base portion can horizontally reciprocate along a rail provided parallel to the transfer direction. The guide portion is provided so as to be capable of horizontally reciprocating in the direction orthogonal to the transfer direction at the base portion. The arm portion is provided at the guide portion so as to be horizontal in the direction parallel to the transfer direction and provided at the position at the side of the placed tray. The inward projecting end, which is the free end of the arm portion, is in contact with and engaged with a part of the projecting portion at the tray from the outer side toward the inner side, and disengaged therefrom from the inner side toward the outer side, due to the horizontal reciprocating movement of the guide portion.

A mechanism including a pair of pulleys spaced in the transfer direction, a wire looped around the pulleys, and a motor connected to one of the pulleys is, for example, used in order to drive the transfer arm.

According to another aspect of the present invention, the substrate transfer apparatus further comprises a rail provided to be parallel to the transfer direction, wherein the transfer arm includes a base portion that can horizontally reciprocate along the rail, a guide portion provided at the base portion so as to be capable of vertically reciprocating in the direction orthogonal to the transfer direction, and an arm portion that is provided horizontally at the guide portion in the direction parallel to the transfer direction and positioned above the placed tray, and that has a downward projecting end, which is the free end, wherein the downward projecting end of the transfer arm is in contact and engaged with and disengaged from the outward projecting portion of the tray when of the guide portion of the transfer arm reciprocates.

The substrate transfer apparatus according to one aspect of the present invention includes the tray as described above having the main body portion having both side edges parallel to the transfer direction, and the outward projecting portion that is formed so as to partially project outwardly from at least one of both side edges of the main body portion, and wherein the transfer arm is in contact and engaged with the outward projecting portion when the tray is transferred by the transfer arm. Further, the transfer arm includes the base portion that can horizontally reciprocate along the rail, the guide portion provided at the base portion so as to be capable of horizontally reciprocating in the direction orthogonal to the transfer direction, and the arm portion that is provided horizontally at the guide portion in the direction parallel to the transfer direction and positioned at the side of the placed tray, and that has the inward projecting end, which is the free end, wherein the inward projecting end of the transfer arm is in contact and engaged with and disengaged from the outward projecting portion of the tray when the guide portion of the transfer arm reciprocates.

Accordingly, in the substrate transfer apparatus described above, the inward projecting end at the arm portion of the transfer arm is in contact with and engaged with a part of the projecting portion at the tray from the outer side toward the inner side due to the horizontal reciprocating movement of the guide portion. Therefore, the tray can be transferred as floated with the arm portion of the transfer arm being engaged with the projecting portion at the tray without the need of the engagement between the fitting holes of the tray and the leading end portion of the transfer arm as in the conventional substrate transfer apparatus. Consequently, the possibility of the trouble related to the transfer as in the conventional case can be prevented.

In the substrate transfer apparatus according to another aspect of the present invention, the downward projecting end of the arm portion of the transfer arm is in contact with and engaged with the projecting portion at the tray from the upper side toward the lower side due to the vertical reciprocating movement of the guide portion. Therefore, the tray can be transferred as floated with the arm portion of the transfer arm being engaged with the projecting portion at the tray without the need of the engagement between the fitting holes of the tray and the leading end portion of the transfer arm as in the conventional substrate transfer apparatus. Consequently, the possibility of the trouble related to the transfer as in the conventional case can be prevented.

The substrate transfer apparatus according to the present invention can be configured such that, as needed, the guide plate has incorporated therein a heater for heating the substrate, and at least the projecting portion of the main body portion and the projecting portion of the tray projects from the side edge of the guide plate, when the tray is placed onto the guide plate.

When the substrate transfer apparatus is configured as described above, the difference in the temperature distribution described above is less generated than in the conventional case during the heating by the heater, since the projecting portion of the tray is provided so as to partially project outwardly from at least one of the both side edges of the main body portion. Accordingly, the possibility of the tray being curved upwardly at the portion close to the side edge is suppressed, whereby the trouble related to the transfer can be prevented.

The tray may be configured such that only the projecting portion of the main body portion and the projecting portion projects from the side edge of the guide plate, when the tray is placed on the guide plate.

When the substrate transfer apparatus is configured as described above, the difference in the temperature distribution described above is less generated than in the conventional case during the heating by the heater. Accordingly, the possibility of the tray being curved upwardly at the portion close to the side edge is more suppressed, whereby the trouble related to the transfer can more be prevented.

The guide plate and the transfer arm may be provided in a vacuum chamber for a plasma process.

In this case, there is no particular limitation on the shape and material of the vacuum chamber, so long as it has a structure capable of being sealed and it can endure a predetermined atmospheric pressure and temperature. For example, a plurality of vacuum chambers can be formed by dividing a single casing, which extends linearly in a longitudinal direction, into a plurality of sections with a separation gate valve that can be opened and closed. The plurality of vacuum chambers are connected to a vacuum pump.

At least one of the plurality of vacuum chambers is defined as a plasma processing chamber for performing a plasma process to a plate-like subject to be processed having a plate shape such as a substrate. The other vacuum chambers are defined as, for example, a subject-to-be-processed carrying-in chamber connected to the plasma processing chamber for carrying in the subject to be processed, or a subject-to-be-processed discharging chamber connected to the plasma processing chamber for discharging the subject to be processed.

In the substrate transfer apparatus according to the present invention, the projecting portion of the tray may have, for example, a base-side edge portion continuous with one side edge of the main body portion, a projecting-side edge portion extending parallel to the base-side edge portion with a predetermined space, and two projecting end portions communicating with these edge portions. The projecting portion of the tray is configured, for example, to have a rectangular planar shape, wherein the length of the base-side edge portion is longer than the length of the projecting end portion, or is configured to have a trapezoidal planar shape, wherein the length of the projecting-side edge portion is longer than the length of the base-side edge portion.

When the projecting portion of the tray is configured as described above, the inward projecting end or the suspending end of the arm portion at the transfer arm is hooked to the projecting end portion of the projecting portion of the tray having the rectangular or trapezoidal planar shape, or to the acute-angled portion formed by the projecting end portion and the projecting-side edge portion. Therefore, the arm portion of the transfer arm can more surely be engaged with the projecting portion of the tray.

The projecting portion of the tray may be configured to have a U-shaped planar shape, which is formed by cutting an area including the middle portion of the projecting-side edge portion from the rectangle having the base-side edge portion continuous with one side edge of the main body portion and the projecting-side edge portion extending parallel to the base-side edge portion with a predetermined space.

When the projecting portion of the tray is configured as described above, the inward projecting end or the suspending end of the arm portion of the transfer arm is engaged with the U-shaped portion of the projecting portion of the tray having the U-shaped planar shape. Therefore, the tray can be transferred in both the forward transfer direction and the rearward transfer direction along the side edge of the tray by the transfer arm.

In the substrate transfer apparatus according to the present invention, it is preferable that the projecting portion of the tray is formed at both sides corresponding to both side edges of the main body portion, and a pair of transfer arms is provided corresponding to the projecting portion at both sides of the tray.

When the projecting portion of the tray and the transfer arm in the substrate transfer apparatus are configured as described above, a pair of the transfer arm is engaged respectively with the projecting portions at both sides. Therefore, the transfer of the tray by the transfer arm can become more stable.

It is more preferable that the projecting portion of the tray is formed in plural number at both sides of the main body portion in the transfer direction with a predetermined space.

When the projecting portion of the tray is configured as described above, a pair of the transfer arms is respectively engaged with a plurality of projecting portions at both sides of the tray. Therefore, the transfer of the tray by the transfer arm can become more sure and stable.

The substrate transfer apparatus according to the present invention can be configured such that the main body portion of the tray has a taper portion at both end portions orthogonal to the transfer direction, of which thickness is gradually reduced toward the outer side that is the direction parallel to the transfer direction.

When the substrate transfer apparatus is configured as described above, even if the tray hangs down at the end portion because of the own weight of the tray or other causes during the transfer of the tray, the tray is transferred by the taper portion at the end portion without being hooked by the end portion of the adjacent guide plate, and guided slidingly to the top surface of the guide plate.

The substrate transfer apparatus according to the present invention can be configured such that the tray further includes a pair of holding portions for holding the tray with both hands at one end of the main body portion in the direction orthogonal to the transfer direction.

When the substrate transfer apparatus is configured as described above, an operator can hold the pair of holding portions of the tray with both hands. Therefore, the movement of the tray can simply and efficiently be carried out.

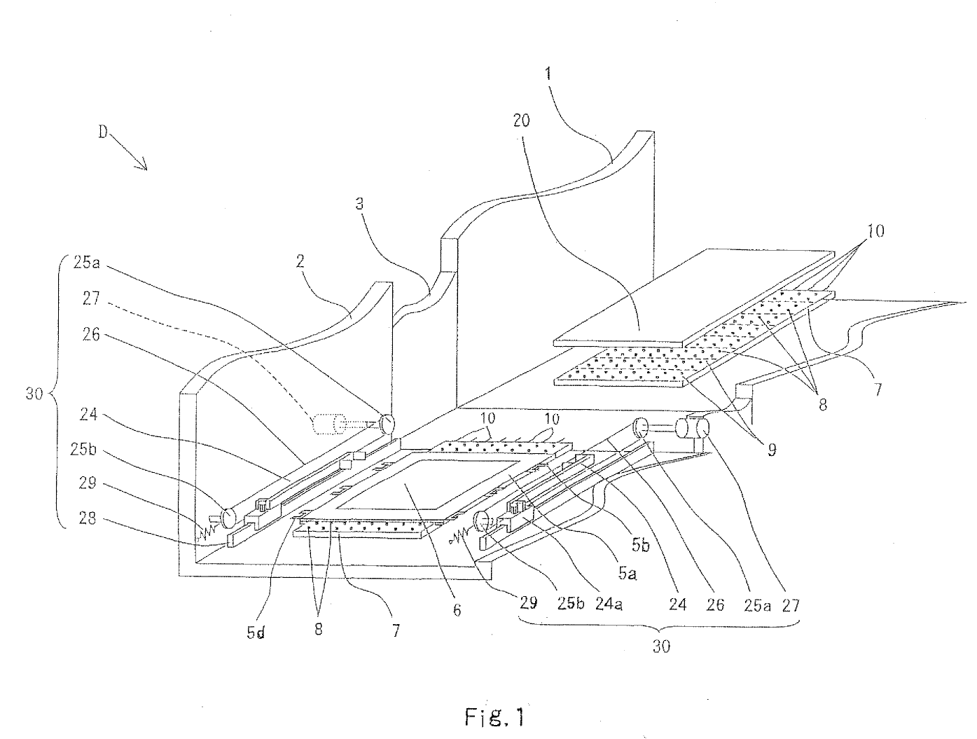

Three preferable embodiments of the present invention will be described with reference to the FIGS. 1 to 13 as accompanying drawings. It is to be noted that the present invention is not limited by these embodiments.

### First Embodiment

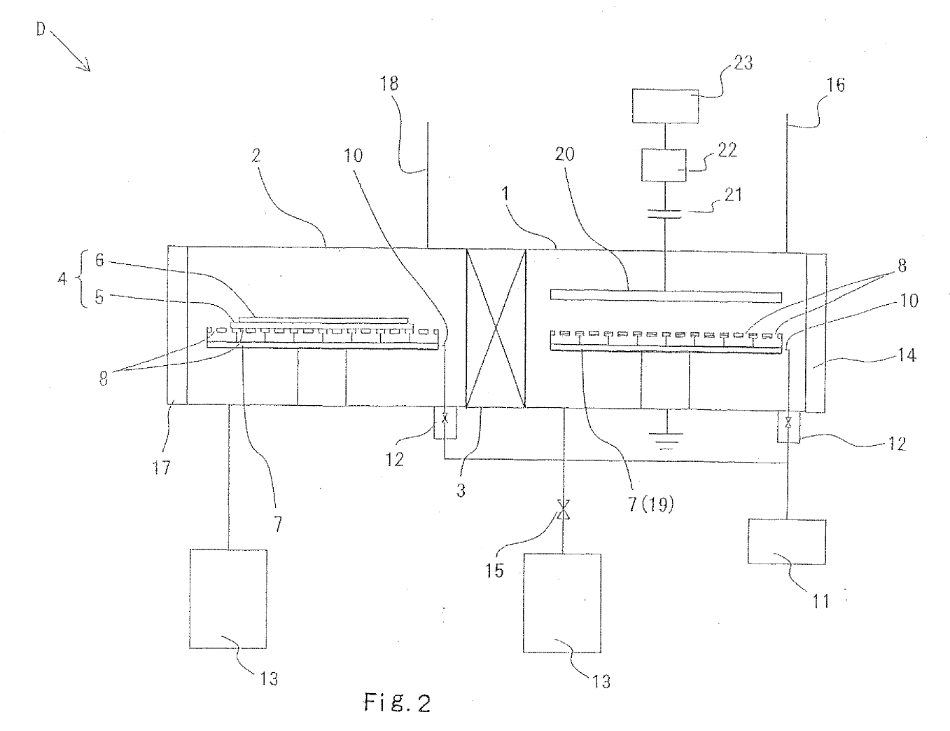

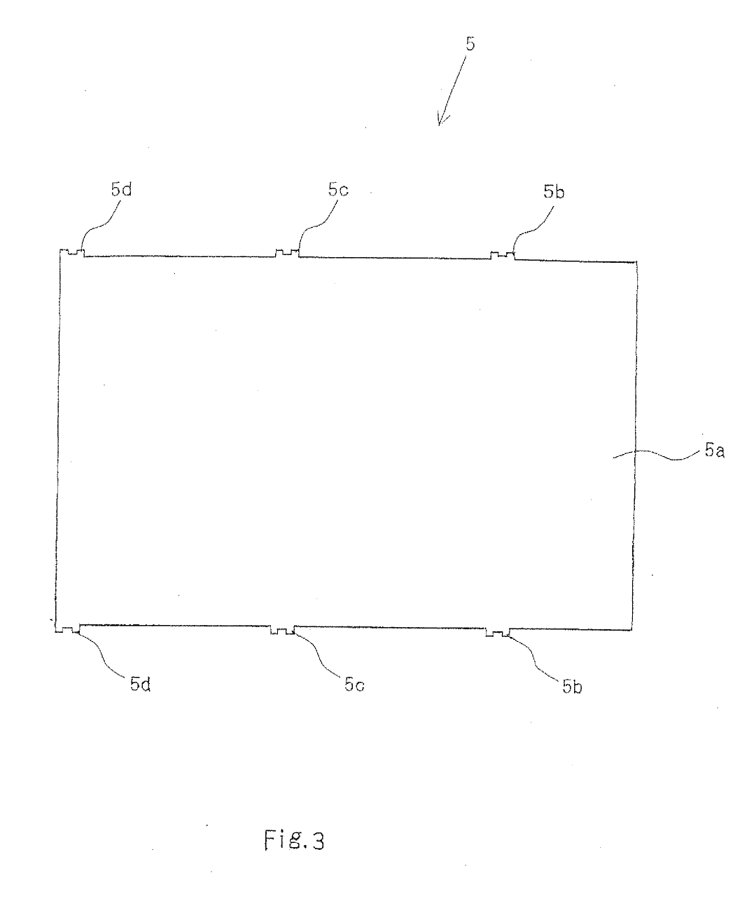

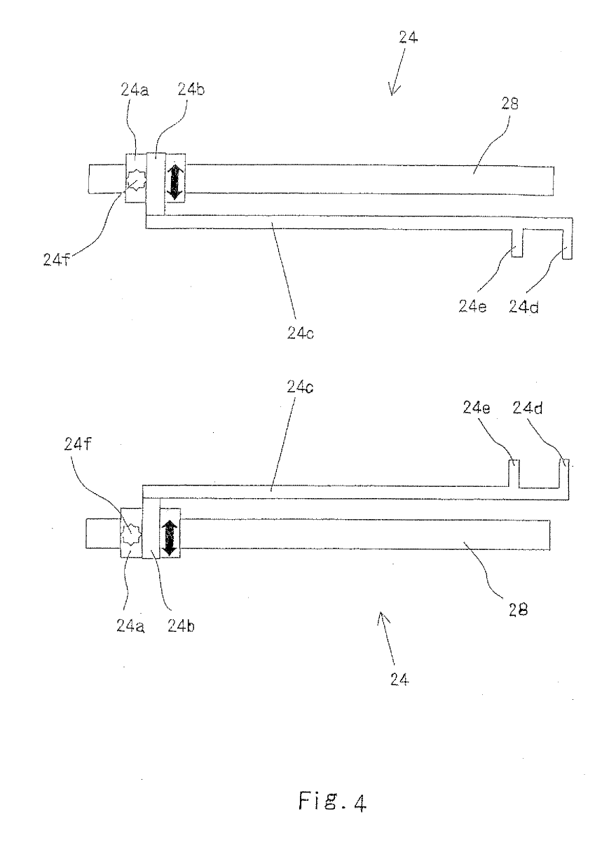

FIG. 1 is a partially cutout perspective view of a substrate transfer apparatus, which is incorporated in a plasma processing apparatus, according to a first embodiment of the present invention. FIG. 2 is a view for explaining the configuration of the substrate transfer apparatus shown in FIG. 1. FIG. 3 is a plan view of a tray, which is one component in the substrate transfer apparatus shown in FIG. 1. FIG. 4 is a plan view of a transfer arm, which is another component in the substrate transfer apparatus shown in FIG. 1.

As shown in FIGS. 1 and 2, the substrate transfer apparatus D according to the first embodiment of the present invention is incorporated in a plasma processing apparatus. The substrate transfer apparatus D has a first vacuum chamber 1 and a second vacuum chamber 2 that are adjacent to each other with a space from the upstream side to the downstream side in a transfer direction. These two vacuum chambers 1 and 2 are configured such that one casing linearly extending in a longitudinal direction is divided into two by a single separation gate valve 3 that can be opened and closed. The vacuum chambers 1 and 2 are made of stainless steel, and a mirror finish is provided on an inner surface thereof. The gate valve 3 is configured to be capable of moving up and down. The gate valve 3 allows the adjacent two vacuum chambers 1 and 2 to communicate with each other when it is at the moving-up position, while it allows the adjacent two vacuum chambers 1 and 2 to be separated from each other when it is at the moving-down position.

The first vacuum chamber 1 is defined as a plasma processing chamber for performing a plasma process to a plate-like subject to be processed 4 having a flat plate shape (here, it is a tray 5 and a plasma processing substrate 6 to be mounted on the tray 5) transferred here from the upstream side in the transfer direction. The second vacuum chamber 2 is defined as a subject-to-be-processed discharging chamber for discharging the subject to be processed 4 to which the plasma process is performed in the plasma processing chamber that is the first vacuum chamber 1.

The plasma processing chamber 1 serving as the first vacuum chamber and the subject-to-be-processed discharging chamber 2 serving as the second vacuum chamber are provided with guide plates 7 that are rectangular flat plates, and are used for a floating transfer, and on which the subject to be processed 4 is placed. These guide plates 7, 7 have partially a hollow structure as described later. The guide plates 7, 7 are made of metal such as stainless steel or aluminum alloy. It is desirable that the material of the guide plates 7, 7 has a hardness higher than that of the material of the tray 5 in order to prevent the deformation or abrasion of the guide plates 7, 7 when the tray 5 and the guide plates 7, 7 are brought into contact with each other during the transfer of the tray 5. The surface of each of the guide plates 7 is subject to a mirror finish. Each of the guide plates has a width (a length of a short side) of 600 mm, a length (a length of a long side) of 1000 mm, and a thickness of 30 mm. The two guide plates 7, 7 are arranged on one line along the transfer direction in the plasma processing chamber 1 and the subject-to-be-processed discharging chamber 2 that are adjacent to each other via the gate valve 3. Each of the guide plates 7 has incorporated therein a heater (not shown) for heating the substrate 6.

As shown in FIGS. 1 and 2, each of the guide plates 7 is formed with a plurality of floating gas ejecting holes 8, . . . 8. Specifically, 128 circular gas ejecting holes in total 8, . . . 8 are formed on a top surface of each of the guide plates 7, in which 8 holes are formed in one row in a direction in which the short side of a rectangle extends (the direction orthogonal to the transfer direction), and the holes are formed in 16 rows in a direction in which the long side of the rectangle extends (the direction parallel to the transfer direction). The diameter of each of the gas ejecting holes 8 is 1.0 mm.

These 128 gas ejecting holes 8, . . . 8 are divided into independent 8 band-like ejecting hole groups 9, . . . 9 including 2 rows having 16 holes. These ejecting hole groups 9, . . . 9 are transversely formed in the transfer direction, which is the direction in which the long side of the guide plate 7 extends, and formed with a predetermined space in the transfer direction.

Each of the guide plates 7 has 8 inner grooves (not shown) corresponding to 8 band-like ejecting hole groups 9, . . . 9, which are transversely formed in the transfer direction, and formed with a predetermined space in the transfer direction, and 8 floating gas supplying tubes 10, . . . 10 that are connected so as to communicate with these inner grooves and extend along the transfer direction in the guide plate 7. Since the guide plate 7 is formed with the inner grooves, the guide plate 7 is hollow at the portions of the inner grooves.

As shown in FIG. 2, the substrate transfer apparatus D has a gas supplying source 11 for supplying the floating gas to the guide plates 7, 7 in the plasma processing chamber 1 and the subject-to-be-processed discharging chamber 2. The gas supplying source 11 is connected to the gas supplying tubes 10, . . . 10 of the guide plates 7, 7 through floating-gas supplying valves 12, 12 provided at an outside of a bottom wall of the plasma processing chamber 1 and the subject-to-be-processed discharging chamber 2.

The plasma processing chamber 1 and the subject-to-be-processed discharging chamber 2 are connected to external vacuum pumps 13, 13. A door 14 for carrying in the subject to be processed is provided at an inlet side of the plasma processing chamber 1. The plasma processing chamber 1 is connected to the vacuum pump 13 below the chamber 1 via a pressure regulating valve 15 for keeping the interior of the chamber to have a predetermined vacuum. The plasma processing chamber 1 is also connected at the upper side to a reaction gas introducing tube 16 for introducing a reaction gas for the plasma process. A door 17 for discharging the subject to be processed is provided to the subject-to-be-processed discharging chamber 2 at its outlet side. The subject-to-be-processed discharging chamber 2 is also connected at the upper side to a leak gas introducing tube 18.

The guide plate 7 in the plasma processing chamber 1 also serves as a plasma-processing anode electrode 19. A plasma-processing cathode electrode 20 is provided above the anode electrode 19 so as to oppose to the anode electrode 19. The cathode electrode 20 is electrically connected to a high-frequency power supply 23 through a condenser 21 and a rectifying circuit 22 at the outside of the plasma processing chamber 1.

As shown in FIGS. 1 and 2, a single plate-like tray 5 is placed onto the guide plate 7 in the subject-to-be-processed discharging chamber 2. The tray 5 has a rectangular planar shape. The tray 5 can be made of metal such as stainless steel or aluminum alloy. It is also desirable that the material of the tray 5 has hardness lower than that of the material of the guide plates 7, 7. For example, the guide plates 7, 7 are made of stainless steel, while the tray 5 is made of an aluminum alloy. Alternatively, the guide plates 7, 7 and the tray 5 are made of stainless steel or an aluminum alloy, wherein the composition ratio may be adjusted to lower the hardness of the tray 5 than the hardness of the guide plates 7, 7. A back surface of the tray 5 (the opposite surface of the guide plate 7) is subject to a mirror finish in order to realize a smooth transfer. The tray 5 has a width (a length of a short side) of 605 mm, a length (a length of a long side) of 900 mm, and a thickness of 2 mm. The tray 5 is placed onto the guide plate 7 for having the substrate 6, which is to be transferred, mounted thereon, and floated by means of a floating gas.

As shown in FIG. 3, the tray 5 has a rectangular main body 5a having both side edges parallel to the transfer direction, and six projecting portions 5b, 5b, 5c, 5c, 5d, and 5d, which are formed to partially project from both side edges of the main body 5a and are brought into contact with and engaged with the transfer arm 24 or disengaged therefrom when the tray 5 is transferred by the later-described transfer arm 24.

The projecting portions 5b, 5b, 5c, 5c, 5d, and 5d of the tray 5 are made up of the first projecting portions 5b, 5b formed at the position of the side edge in the main body 5a close to the upstream side in the transfer direction, second projecting portions 5c, 5c formed at the middle position apart from the first projecting portions 5b, 5b with a predetermined space toward the downstream side in the transfer direction, and third projecting portions 5d, 5d formed at the end position communicating with the end portions at the downstream side in the transfer direction apart from the second projecting portions 5c, 5c with a predetermined space toward the downstream side in the transfer direction. Each of the projecting portions bb, . . . 5d has an U-shaped planar shape. Specifically, each of the projecting portions 5b, . . . 5d is formed to have an U-shaped planar shape as shown in FIG. 3, wherein it has a rectangular shape including a baseside edge portion communicating with one side edge of the main body 5a and a projecting-side edge portion extending parallel to the base-side edge portion with a predetermined space, in which a small rectangular region including the middle portion of the projecting-side edge portion is cut out.

The substrate transfer apparatus D has transfer function units 30, 30 provided to the subject-to-be-processed discharging chamber 2. The transfer function units 30, 30 allow the subject to be processed 4 placed onto the guide plate 7 to float, and transfer the floated subject to be processed 4 between the plasma processing chamber 1 and the subject-to-be-processed discharging chamber 2 along the guide plates 7, 7 with external force. The floating transfer by the transfer function units 30, 30 will be described with reference to FIGS. 1 to 4 below.

In FIG. 1, each of the transfer function units 30, 30 moves the subject to be processed 4 between the plasma processing chamber 1 and the subject-to-be-processed discharging chamber 2. Each of the transfer function units 30, 30 has a transfer arm 24 arranged along both side edges of the subject to be processed 4 in the subject-to-be-processed discharging chamber 2, a pair of pulleys (a drive pulley 25a and a driven pulley 25b) arranged in the transfer direction with a space, a wire 26 looped around these pulleys 25a and 25b, and a motor 27 connected to the drive pulley 25a.

A spring 29 that is urged in a direction of taking up the slack of the wire 26 is mounted to the driven pulley 25b. The spring 29 pulls the driven pulley 25b in the direction parallel to the transfer direction, so that the tension of the wire 26 is kept to be constant.

As shown in FIGS. 1 and 4, the transfer arm 24 includes a base portion 24a, a guide portion 24b, and an arm portion 24c. A part of the transfer arm 24 is coupled to the wire 26, and placed onto a rail 28 provided horizontally at the rearward of the bottom surface of the subject-to-be-processed discharging chamber 2.

Specifically, the base portion 24a is coupled to the wire 26 and mounted to the rail 28, so that the base portion 24a can reciprocate horizontally along the rail 28. The guide portion 24b can reciprocate horizontally in the direction (the direction indicated by both arrows in FIG. 4) orthogonal to the transfer direction at the base portion 24a. The arm portion 24c is provided horizontally in the direction parallel to the transfer direction at the guide portion 24b, and provided so as to be positioned at the side of the placed tray 5. The moving distance of the arm portion 24c in the transfer direction is set to be 650 mm.

The arm portion 24c is formed with first and second inward projecting ends 24d and 24e at its free end. The inward projecting ends 24d and 24e are brought into contact with each of the first to third projecting portions 5b, . . . 5d so as to be engaged therewith or are disengaged from each of the first to third projecting portions 5b, . . . 5d in the tray 5.

More specifically described, a gear 24f is provided at the top surface of the base portion 24a via a vertical rotational axis (not shown). The gear 24f is supported to the base portion 24a so as to be rotatable. When the gear 24f is rotatably engaged with one side face of the guide portion 24b (the side face where a gear groove engaged with the gear 24f is formed), it allows the guide portion 24b to reciprocate in the directions indicated by the arrows.

Due to the reciprocating movement of the guide portion 24b, the arm 24c is apart from the rail 28 or close to the rail 28 with the parallel relationship between the arm portion 24c and the rail 28 maintained. With the movement of the arm portion 24c described above, the inward projecting ends 24d and 24e at the arm portion 24c is brought into contact with one of the projecting portions 5b, . . . 5d at the tray 5 so as to be engaged therewith from the outer side (the side more apart from the side edge of the main body 5a of the tray 5) toward the inner side (the side closer to the side edge of the main body 5a of the tray 5), or disengaged from one of the projecting portions 5b, . . . 5d at the tray 5 from the inner side toward the outer side.

The plasma processing apparatus D further includes a sensor (not shown) for detecting the position of the tray 5 that is now being transferred, and a control function unit (not shown) for performing a predetermined control.

The control function unit mainly performs the control described below. Specifically, it opens the gate valve 3 so as to allow the adjacent plasma processing chamber 1 and the subject-to-be-processed discharging chamber 2 to communicate with each other. Further, the control function unit allows the floating gas to be ejected from the gas ejecting holes 8, . . . 8 at the guide plates 7, 7 in the plasma processing chamber 1 and the subject-to-be-processed discharging chamber 2. Then, the control function unit causes the floating gas to be sequentially ejected from the ejecting hole groups 9, . . . 9 involved with the floating of the subject to be processed 4 in the plasma processing chamber 1 and the subject-to-be-processed discharging chamber 2 in order to make the floating transfer control for transferring the subject to be processed 4 (tray 5+substrate 6), which is floated by the ejected floating gas, along the guide plates 7, 7 by the transfer function units 30, 30. The control function unit also sequentially stops the ejection of the floating gas from the ejecting hole groups 9, . . . 9 that are not involved with the floating of the subject to be processed 4.

A subject-to-be-processed carrying-in chamber (not shown) is provided at the upstream side of the plasma processing chamber 1 in the transfer direction in FIGS. 1 and 2. In the subject-to-be-processed carrying-in chamber, a floating-transfer guide plate (not shown) on which the subject to be processed 4 (tray 5+substrate 6) is placed and a transfer function unit (not shown) are provided. The substrate 6 is mounted on the guide plate via the tray 5. With this state, the tray 5 in the subject-to-be-processed carrying-in chamber covers the central six ejecting hole groups of eight band-like ejecting hole groups, like the subject-to-be-processed discharging chamber 2 shown in FIGS. 1 and 2. The transfer function unit in the subject-to-be-processed carrying-in chamber has the structure same as that of the transfer function units 30, 30 in the subject-to-be-processed discharging chamber 2. The transfer function units in the subject-to-be-processed carrying-in chamber are provided so as to be symmetry with the transfer function units 30, 30 in the subject-to-be-processed discharging chamber 2 with respect to a plane.

The floating transfer operation of the plasma processing apparatus D will be described below, wherein the operation is made by the combination of the transfer function units in the subject-to-be-processed carrying-in chamber, the transfer function units 30, 30 in the subject-to-be-processed discharging chamber 2, and the control function unit. The components in the subject-to-be-processed carrying-in chamber corresponding to the components in the subject-to-be-processed discharging chamber 2 are indicated by numerals in parentheses (for example, “guide plate (7)” for descriptive purposes.

The control function unit causes the floating gas (here, nitrogen gas) to eject from the gas ejecting holes (8, . . . 8) on the guide plates (7) in the subject-to-be-processed carrying-in chamber, so that the subject to be processed (4) is floated from the guide plates (7). The control function unit moves the transfer arm (24) horizontally along the rail (28) toward the downstream side in the transfer direction, wherein the inward projecting ends (24d, 24e) at the arm portion (24c) move from the outer side toward the inner side to be brought into contact with and engaged with the third projecting portion (5d) at the end at the downstream side in the transfer direction. In this case, the tray (5) is floated, whereby the arm portion (24c) of the transfer arm (24) can smoothly transfer the tray (5) with slight force.

The control function unit does not cause the floating gas to be ejected from all gas ejecting holes (8, . . . 8) on the guide plates (7) all at once, but causes the floating gas to be sequentially ejected from the ejecting hole groups (9, . . . 9) involved with the floating of the subject to be processed (4). Specifically, the control function unit causes the floating gas to be sequentially ejected from the ejecting hole groups (9, . . . 9) involved with the floating of the subject to be processed (4), and sequentially stops the ejection of the floating gas from the ejecting hole groups (9, . . . 9) that become uninvolved with the floating of the subject to be processed (4), according to the position of the tray (5) detected by the sensor, which detects the position of the tray (5) that is being transferred.

The ejection of the floating gas described above is executed by the control function unit that operates the flow rate regulating valve 12 connected to the respective gas supplying sources 11.

The sequential ejection and sequential stop of the ejection of the floating gas by the control function unit described above is continuously done even in a state in which the leading end of the tray (5) in the advancing direction is transferred from the guide plate (7) in the subject-to-be-processed carrying-in chamber to the guide plate 7 in the plasma processing chamber 1 according to the progress of the transfer of the tray (5).

When the arm portion (24c) of the transfer arm (24) horizontally moves toward the downstream side in the transfer direction with a fixed distance in the subject-to-be-processed carrying-in chamber, the inward projecting ends (24d, 24e) of the arm portion (24c) moves from the inner side toward the outer side to be disengaged from the third projecting portion (5d) at the tray (5). Then, the arm portion (24c) further horizontally moves toward the downstream side in the transfer direction with a fixed distance, wherein the inward projecting ends (24d, 24e) moves again from the outer side toward the inner side to be in contact with and engaged with the second projecting portion (5c) at the tray (5). Thereafter, the inward projecting ends (24d, 24e) of the arm portion (24c) moves again from the inner side toward the outer side to be disengaged from the second projecting portion (5c) at the tray (5).

Then, the arm portion (24c) further horizontally moves toward the downstream side in the transfer direction with a fixed distance, wherein the inward projecting ends (24d, 24e) moves again from the outer side toward the inner side to be in contact with and engaged with the first projecting portion (5b) at the tray (5). As a result, the tray (5) and the substrate (6) in the subject-to-be-processed carrying-in chamber is transferred to the central position of the guide plate 7 in the plasma processing chamber 1, whereby it is sandwiched between the guide plate 7, serving as the anode electrode, and the cathode electrode 20 above the guide plate 7.

Next, the control function unit stops the ejection of the floating gas from the guide plate 7 in the plasma processing chamber 1, and places the tray 5 onto the guide plate 7 for positioning. Then, the gate valve, which is at the lifted position, is moved down to again separate the subject-to-be-processed carrying-in chamber and the plasma processing chamber 1.

Then, the control function unit operates the vacuum pump 13 (see FIG. 2) connected to the plasma processing chamber 1 so as to keep the plasma processing chamber 1 to have a predetermined vacuum. Thereafter, a predetermined plasma process is performed to the substrate 6 on the tray 5 by the guide plate 7, serving as the anode electrode, and the cathode electrode 20 above the guide plate 7.

The substrate 6 that is subject to the predetermined plasma process in the plasma processing chamber 1 is floated and transferred, as being mounted on the tray 5, to the subject-to-be-processed discharging chamber 2 by the transfer function units 30, 30 in the subject-to-be-processed discharging chamber 2 and the control function unit. The description relating to the floating of the tray 5 is substantially the same as that mentioned above, so that the description will not be repeated.

By means of the control function unit, the arm portion 24c of the transfer arm 24 of each of the transfer function units 30 horizontally moves toward the downstream side in the transfer direction along the corresponding rail 28 with a fixed distance, wherein the inward projecting ends 24d and 24e move from the outer side toward the inner side to be in contact with and engaged with the third projecting portion 5d, which is at the end of the tray 5 having the substrate 6 mounted thereon in the plasma processing chamber 1 at the downstream side in the transfer direction. By virtue of this movement, the inward projecting ends 24d and 24e at the arm portion 24c of each of the transfer arms 24 move from the inner side toward the outer side to be disengaged from the third projecting portion 5d at the tray 5.

Then, the arm 24c further horizontally moves toward the downstream side in the transfer direction with a fixed distance, wherein the inward projecting ends 24d and 24e move again from the outer side toward the inner side to be in contact with and engaged with the second projecting portion 5c formed at the middle portion of the tray 5. By virtue of this movement, the inward projecting ends 24d and 24e at the arm portion 24c again move from the inner side toward the outer side to be disengaged from the second projecting portion 5c at the tray 5. Thereafter, the arm 24c further horizontally moves toward the downstream side in the transfer direction with a fixed distance, wherein the inward projecting ends 24d and 24e are in contact with and engaged with the first projecting portion 5b formed at the position close to the end of the tray 5 at the upstream side in the transfer direction. Consequently, the tray 5 and the substrate 6 in the plasma processing chamber 1 are transferred to the central position on the guide plate 7 in the subject-to-be-processed discharging chamber 2 as shown in FIGS. 1 and 2.

According to the substrate transfer apparatus D according to the first embodiment of the present invention, the inward projecting ends 24d and 24e at the arm portion 24c of the transfer arm 24 are brought into contact with and engaged with one of the projecting portions 5b, . . . , 5d at the tray 5 from the outer side to the inner side due to the horizontal reciprocating movement of the guide portion 24b. The tray 5 can be transferred as floated with the state in which the arm portion 24c of the transfer arm 24 is engaged with the projecting portions 5b, . . . 5d at the tray 5, without the engagement between the fitting holes at the tray and the leading end of the transfer arm as in the conventional substrate transfer apparatus. Therefore, the possibility of the trouble related to the transfer as in the conventional case can be prevented.

### Second Embodiment

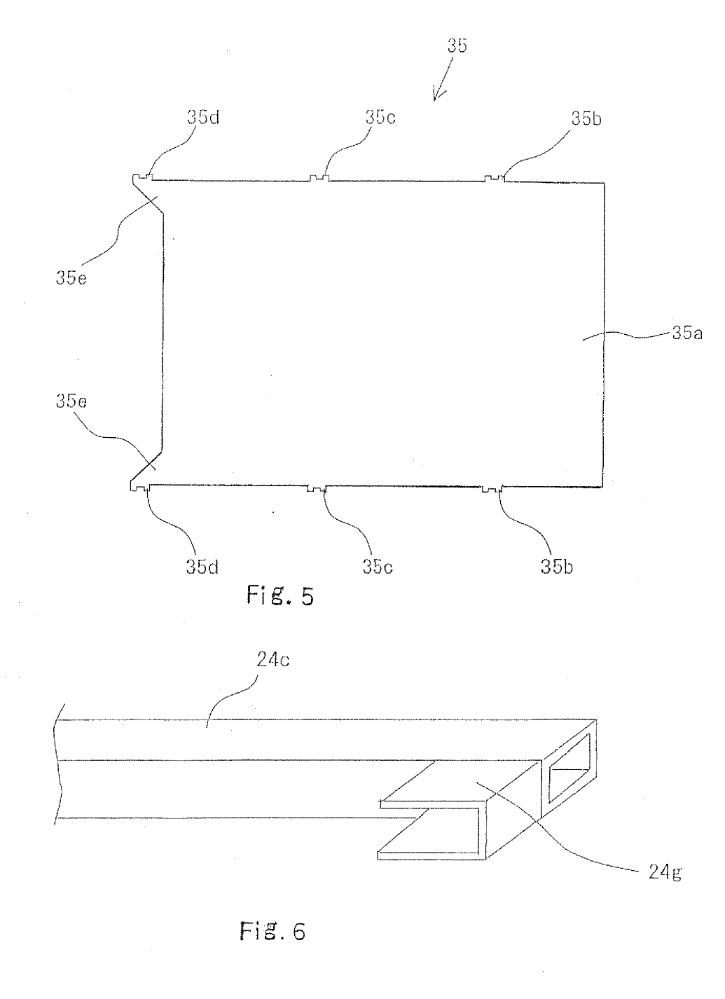

FIG. 5 is a plan view of a tray, which is one component of a substrate transfer apparatus incorporated in a plasma processing apparatus according to a second embodiment of the present invention. FIG. 6 is a perspective view of an arm portion of a transfer arm that is another component of the substrate transfer apparatus according to the second embodiment of the present invention.

The substrate transfer apparatus according to the second embodiment includes the subject-to-be-processed discharging chamber, plasma processing chamber, and subject-to-be-processed carrying-in chamber, those of which are the same as those in the substrate transfer apparatus D in the first embodiment. As shown in FIG. 5, in the substrate transfer apparatus, a tray 35 is used instead of the tray 5 in the substrate transfer apparatus D in the first embodiment. Like the tray 5 in the first embodiment, the tray 35 is made of metal such as stainless steel or aluminum alloy, and its back surface is subject to a mirror finish for realizing a smooth transfer.

The tray 35 has a rectangular main body 35a having both side edges parallel to the transfer direction, and six projecting portions 35b, 35b, 35c, 35c, 35d, and 35d, which are formed to partially project outwardly from both side edges of the main body 35a and are brought into contact with and engaged with the transfer arm 24 or disengaged therefrom when the tray 35 is transferred by the transfer arm 24. The tray 35 is configured such that, when it is mounted to the guide plate in the subject-to-be-processed carrying-in chamber, plasma processing chamber, and subject-to-be-processed discharging chamber, only the projecting portions 35b, . . . 35d of the main body 35a and the projecting portions 35b, . . . 35d protrude from the side edge of the guide plate.

The projecting portions 35b, . . . 35d at the tray 35 are the same as those at the tray 5 in the substrate transfer apparatus D in the first embodiment. The tray 35 is further provided with a pair of holding portions 35e, 35e for holding the tray 35 with both hands at one end portion of the main body 35a orthogonal to the transfer direction.

The transfer arm same as that in the substrate transfer apparatus D in the first embodiment is provided to the substrate transfer apparatus. The transfer arm has a base portion 24a, guide portion 245, and arm portion 24c like the transfer arm 24 in the substrate transfer apparatus D in the first embodiment.

As shown in FIG. 6, an inward projecting end 24g is provided at the free end of the arm portion 24c. The inward projecting end 24g is formed into a reversed C-shape viewed from the front. Due to the reciprocating movement of the guide portion 24b, it is brought into contact with and engaged with each of the first to third projecting portions 35b, . . . 35d at the tray 35 from the outer side to the inner side or is disengaged therefrom from the inner side to the outer side.

The other configuration of the substrate transfer apparatus in the second embodiment is substantially the same as that of the substrate transfer apparatus D in the first embodiment.

### Modifications of Second Embodiment

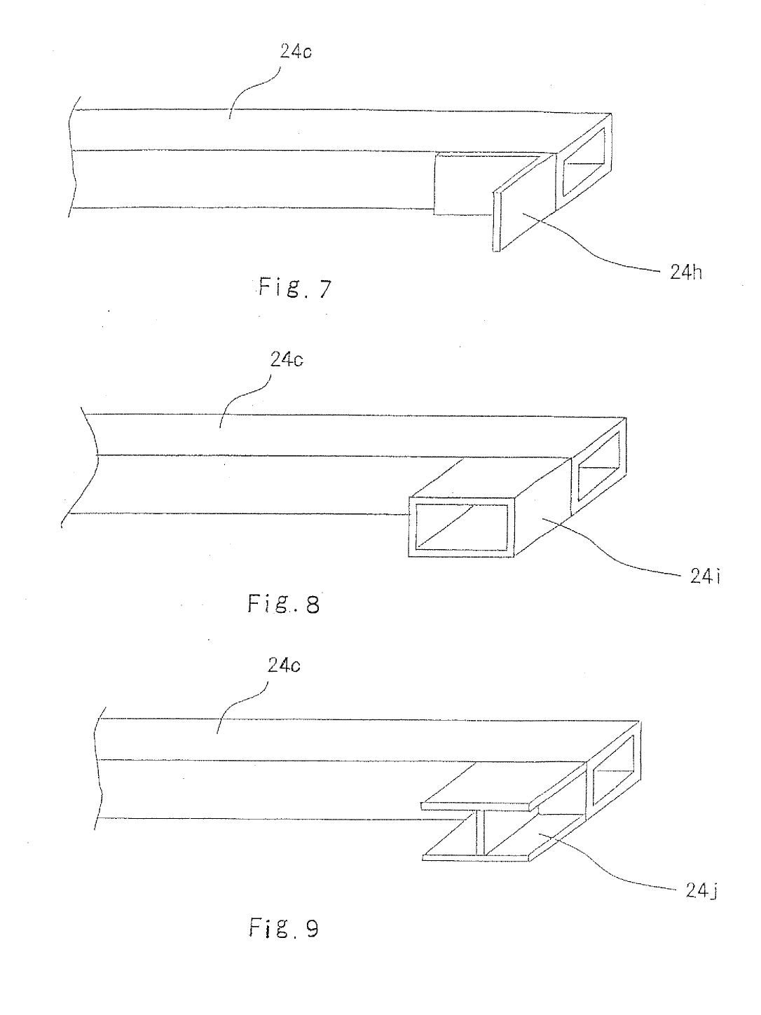

FIGS. 7 to 9 respectively show inward projecting ends 24h, 24i, and 24j (modifications 1 to 3) provided to the free end of the arm portion 24c in the substrate transfer apparatus according to the second embodiment instead of the inward projecting end 24g.

The inward projecting end 24h at an arm portion 24c in a first modification shown in FIG. 7 has an L-shaped planar shape. The inward projecting end 24i at the arm portion 24c in the second modification shown in FIG. 8 is made of a hollow tube having a rectangular-frame like front shape and rectangular planar shape. The inward projecting end 24j at the arm portion 24c in the third modification shown in FIG. 9 is formed into a laid H viewed from the front and has a rectangular planar shape.

### Third Embodiment

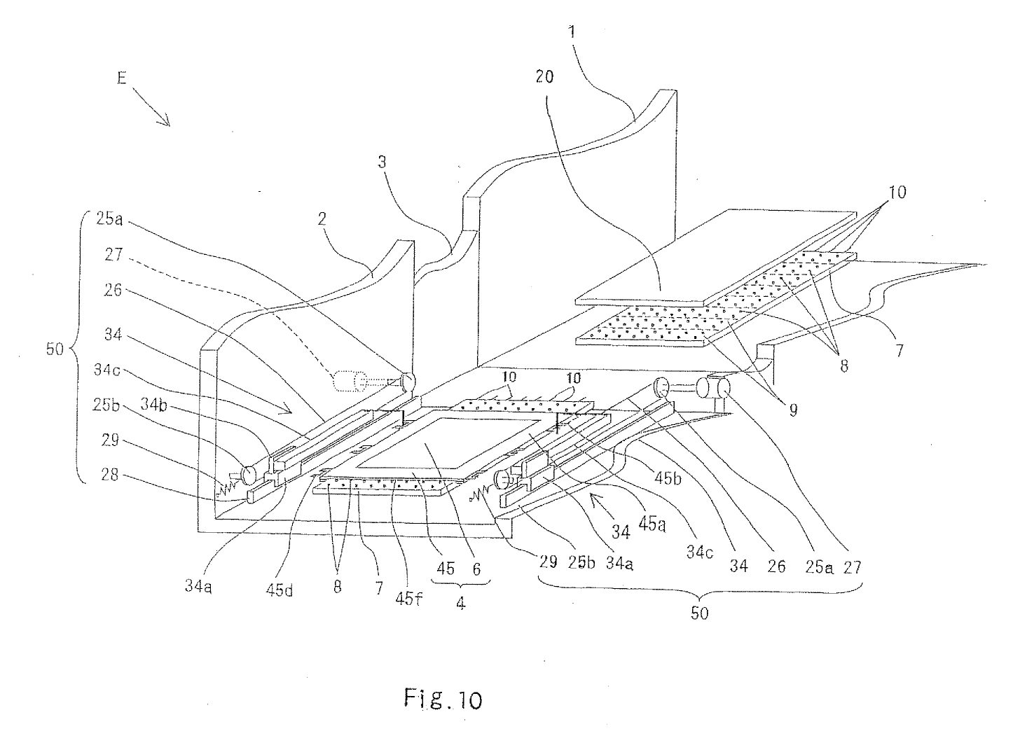

FIG. 10 is a partially cutout perspective view showing a substrate transfer apparatus, which is incorporated in a plasma processing apparatus, according to a third embodiment of the present invention. FIG. 11 is a plan view of a tray, which is one component in the substrate transfer apparatus shown in FIG. 10.

As shown in FIG. 10, the substrate transfer apparatus E according to the third embodiment includes the subject-to-be-processed discharging chamber 2, plasma processing chamber 1, and subject-to-be-processed carrying-in chamber, those of which are the same as those in the substrate transfer apparatus D in the first embodiment. As shown in FIGS. 10 and 11, in the substrate transfer apparatus E according to the third embodiment, a tray 45 is used instead of the tray 5 in the substrate transfer apparatus D in the first embodiment. Like the tray 5 in the first embodiment, the tray 45 is made of metal such as stainless steel or aluminum alloy, and its back surface is subject to a mirror finish for realizing a smooth transfer.

The tray 45 has a rectangular main body 45a having both side edges parallel to the transfer direction, and six projecting portions 45b, 45b, 45c, 45c, 45d, and 45d, which are formed to partially project outwardly from both side edges of the main body 45a and are brought into contact with and engaged with the transfer arm 24 or disengaged therefrom when the tray 35 is transferred by the transfer arm 24.

Taper portions 45e and 45e, which are gradually reduced from the main body 45a toward the outer direction that is parallel to the transfer direction, are respectively formed at both ends of the main body 45a orthogonal to the transfer direction. The structure and size of each of the projecting portions 45b, . . . 45d are the same as those of each of the projecting portions 5b, . . . 5d in the substrate transfer apparatus D according to the first embodiment.

The substrate transfer apparatus E has transfer function units 50, 50 provided to the subject-to-be-processed discharging chamber 2. The transfer function units 50, 50 allow the subject to be processed 4 (tray 45+substrate 6) placed onto the guide plate 7 to float, and transfer the floated subject to be processed 4 between the plasma processing chamber 1 and the subject-to-be-processed discharging chamber 2 along the guide plates 7, 7 with external force.

In FIG. 10, each of the transfer function units 50, 50 move the subject to be processed 4 between the plasma processing chamber 1 and the subject-to-be-processed discharging chamber 2. Each of the transfer function units 50, 50 has a transfer arm 34 arranged along both side edges of the subject to be processed 4 in the subject-to-be-processed discharging chamber 2, a pair of pulleys (a drive pulley 25a and a driven pulley 25b) arranged in the transfer direction with a space, a wire 26 looped around these pulleys 25a and 25b, and a motor 27 connected to the drive pulley 25a.

A spring 29 that is urged in the direction of taking up the slack of the wire 26 is mounted to the driven pulley 25b. The spring 29 pulls the driven pulley 25b in the direction parallel to the transfer direction, so that the tension of the wire 26 is kept to be constant.

The transfer arm 34 includes a base portion 34a, a guide portion 34b, and an arm portion 34c. A part of the transfer arm 34 is coupled to the wire 26, and placed onto a rail 28 provided horizontally at the rearward of the bottom surface of the subject-to-be-processed discharging chamber 2.

Specifically, the base portion 34a is coupled to the wire 26 and mounted to the rail 28, so that the base portion 34a can reciprocate horizontally along the rail 28. The guide portion 34b can move up and down in the vertical direction at the base portion 34a. The arm portion 34c is provided horizontally in the direction parallel to the transfer direction at the guide portion 34b, and provided so as to be positioned above the placed tray 45.

The downward projecting end, which is the free end, of the arm portion 34c moves from the upper side toward the lower side due to the descending movement of the guide portion 34b, whereby it is brought into contact with and engaged with one of the projecting portions 45b, . . . 45d of the tray 45. The arm portion 34c also moves from the lower side toward the upper side due to the ascending movement of the guide portion 34b, whereby it is disengaged from one of the projecting portions 45b, . . . 45d of the tray 45.

The substrate 6 that is subject to the predetermined plasma process in the plasma processing chamber 1 is floated and transferred to the subject-to-be-processed discharging chamber 2, as being placed onto the tray 45, by means of the transfer function units 50, 50 of the subject-to-be-processed discharging chamber 2 and the control function unit. The description related to the floating of the tray 45 is substantially the same as described above, so that it will not repeated here.

Due to the control function unit, the arm portion 34c of the transfer arm 34 horizontally moves along the corresponding rail 28 toward the downstream side in the transfer direction with a fixed distance, wherein the suspending end of the arm portion 34c of the transfer arm 34 at each of the transfer function units 50 moves down so as to be in contact with and engaged with the third projecting portion 45d at the end of the tray 45, having the substrate 6 mounted thereon in the plasma processing chamber 1, at the downstream side in the transfer direction. Then, the suspending end of the arm portion 34c at the transfer arm 34 moves up so as to be disengaged from the third projecting portion 45d of the tray 45.

Next, the arm portion 34c further horizontally moves toward the downstream side in the transfer direction with a fixed distance, wherein the suspending end again moves down to be in contact with and engaged with the second projecting portion 45c formed at the middle position of the tray 45. Then, the suspending end of the arm portion 34c moves up again, whereby it is disengaged from the second projecting portion 45c of the tray 45. Thereafter, the arm portion 34c further horizontally moves toward the downstream side in the transfer direction with a fixed distance, wherein the downward projecting end again moves down to be in contact with and engaged with the first projecting portion 45b formed at the position close to the upstream end in the transfer direction. Consequently, the tray 45 and the substrate 6 in the plasma processing chamber 1 are transferred to the central position on the guide plate 7 in the subject-to-be-processed discharging chamber 2 as shown in FIG. 10.

The other configurations of the substrate transfer apparatus E according to the third embodiment of the present invention are substantially the same as those of the substrate transfer apparatus D according to the first embodiment.

According to the substrate transfer apparatus E according to the third embodiment of the present invention, the downward projecting end at the arm portion 34c of the transfer arm 34 moves from the upper side toward the lower side to be in contact with and engaged with one of the projecting portions 45b, . . . 45d at the tray 45 due to the descending movement of the guide portion 34b. Therefore, the tray 45 can be transferred as floated with the state in which the arm portion 34c of the transfer arm 34 is engaged with the projecting portions 45b, . . . 45d of the tray 45, without the engagement between the fitting holes at the tray and the leading end of the transfer arm as in the conventional substrate transfer apparatus. Therefore, the possibility of the trouble related to the transfer in the conventional case can be prevented.

### Modifications of Third Embodiment

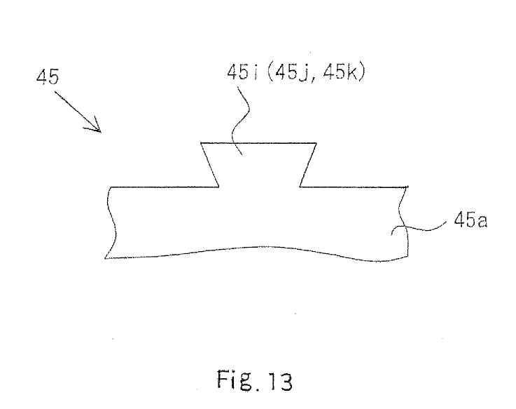

FIGS. 10 and 13 respectively show first to third projecting portions 45f, 45g, 45h; 45i, 45j, 45k (modifications 1 and 2) that are formed instead of the projecting portions 45b, . . . 45d of the tray 45 in the substrate transfer apparatus E according to the third embodiment.

These projecting portions 45f, 45g, 45h; 45i, 45j, 45k respectively have a base-side edge portion communicate with one side edge of the main body portion 45a, a projecting-side edge portion extending so as to be parallel to the baseside edge portion with a space, and two projecting end portions that communicate these edge portions.

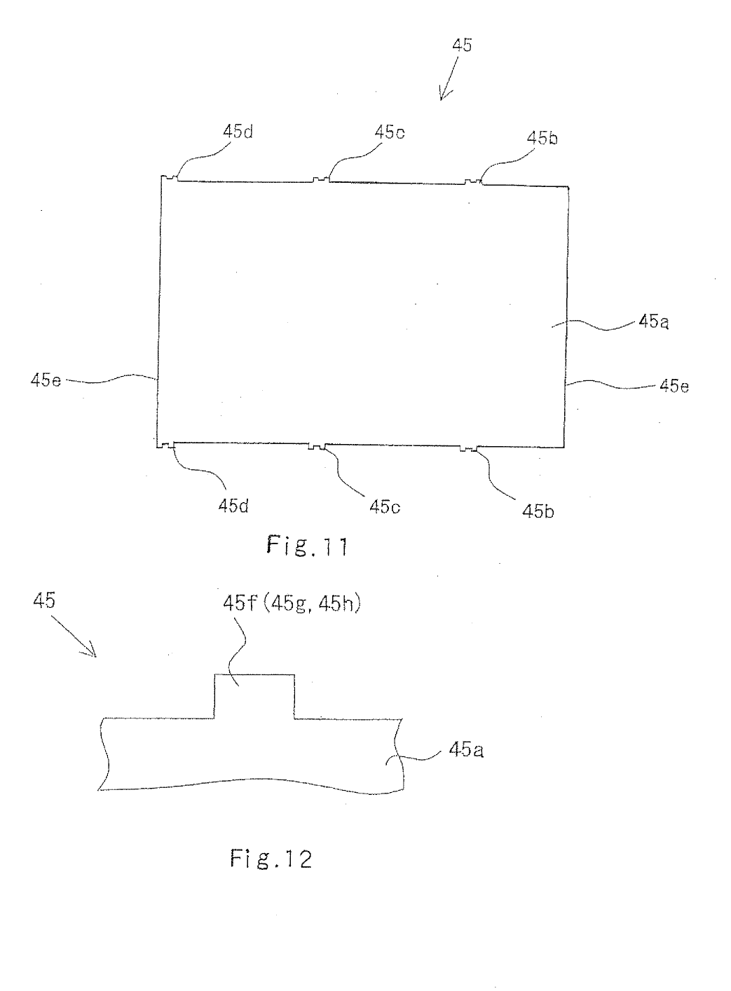

Specifically, the first to third projecting portions 45f, 45g, and 45h of the tray 45 in the first modification shown in FIG. 12 has a rectangular planar shape, wherein the length of the base-side edge portion is longer than the length of the projecting end portion.

The first to third projecting portions 45i, 45j, and 45k of the tray 45 in the second modification shown in FIG. 13 have a planar shape of isosceles trapezoid, wherein the length of the projecting-side edge portion is longer than the length of the base-side edge portion.

What is claimed is:

1. A substrate transfer apparatus comprising:
a plurality of floating-transfer guide plates adjacent to each other with a space, each of guide plate having a plurality of floating gas ejecting holes;
a gas supplying source for supplying a floating gas to the guide plates;
a tray that is placed on one of the guide plates in order to mount a substrate to be transferred, and that is floated by the floating gas; and
a transfer arm for transferring the floated tray to the adjacent other guide plate from the guide plate, wherein
the tray includes a main body portion having both side edges parallel to a transfer direction of the tray, and an outward projecting portion that is formed so as to partially project outwardly from at least one of both side edges of the main body portion,
and wherein the transfer arm is in contact and engaged with the outward projecting portion when the tray is transferred by the transfer arm.

2. The substrate transfer apparatus according to claim 1, further comprising a rail provided to be parallel to the transfer direction, wherein
the transfer arm includes a base portion that can horizontally reciprocate along the rail, a guide portion provided at the base portion so as to be capable of horizontally reciprocating in the direction orthogonal to the transfer direction, and an arm portion that is provided horizontally at the guide portion in the direction parallel to the transfer direction and positioned at a side of the placed tray, and that has an inward projecting end, which is a free end, wherein the inward projecting end of the transfer arm is in contact with and engaged with and disengaged from the outward projecting portion of the tray when of the guide portion of the transfer arm reciprocates.

3. The substrate transfer apparatus according to claim 1, further comprising a rail provided to be parallel to the transfer direction, wherein
the transfer arm includes a base portion that can horizontally reciprocate along the rail, a guide portion provided at the base portion so as to be capable of vertically reciprocating in the direction orthogonal to the transfer direction, and an arm portion that is provided horizontally at the guide portion in the direction parallel to the transfer direction and positioned above the placed tray, and that has a downward projecting end, which is the free end, wherein the downward projecting end of the transfer arm is in contact and engaged with and disengaged from the outward projecting portion of the tray when the guide portion of the transfer arm reciprocates.

4. The substrate transfer apparatus according to claim 1, wherein
the guide plate has incorporated therein a heater for heating the substrate, and the tray is configured such that at least the projecting portion of the main body portion and the projecting portion projects from the side edge of the guide plate, when the tray is placed onto the guide plate.

5. The substrate transfer apparatus according to claim 4, wherein
the tray is configured such that only the projecting portion of the main body portion and the projecting portion projects from the side edge of the guide plate, when the tray is placed onto the guide plate.

6. The substrate transfer apparatus according to claim 1 further comprising a vacuum chamber, wherein
the guide plate and the transfer arm are provided in the vacuum chamber.

7. The substrate transfer apparatus according to claim 1, wherein
the projecting portion of the tray has a base-side edge portion communicating with one side edge of the main body portion, a projecting-side edge portion extending parallel to the base-side edge portion with a predetermined space, and two projecting end portions communicating with these edge portions.

8. The substrate transfer apparatus according to claim 7, wherein
the projecting portion of the tray has a rectangular planar shape, wherein the length of the base-side edge portion is longer than the length of the projecting end portion.

9. The substrate transfer apparatus according to claim 7, wherein
the projecting portion of the tray has a trapezoidal planar shape, wherein the length of the projecting-side edge portion is longer than the length of the base-side edge portion.

10. The substrate transfer apparatus according to claim 1, wherein
the projecting portion of the tray is configured to have a U-shaped planar shape, which is formed by cutting an area including a middle portion of the projecting-side edge portion from a rectangle having the base-side edge portion communicating with one side edge of the main body portion and the projecting-side edge portion extending parallel to the base-side edge portion with a predetermined space.

11. The substrate transfer apparatus according to claim 1, wherein
the projecting portion of the tray is provided at both sides corresponding to both side edges of the main body portion, and a pair of the transfer arms is provided corresponding to the projecting portions at both sides of the tray.

12. The substrate transfer apparatus according to claim 11, wherein
the projecting portion of the tray is provided in plural number at both sides of the main body portion with a predetermined space in the transfer direction.

13. The substrate transfer apparatus according to claim 1, wherein
the main body portion of the tray has a taper portion at both end portions orthogonal to the transfer direction, of which thickness is gradually reduced toward the outer side that is the direction parallel to the transfer direction.

14. The substrate transfer apparatus according to claim 1, wherein
the tray further has a pair of holding portions for holding the tray with both hands at one end of the main body portion in the direction orthogonal to the transfer direction.

15. The substrate transfer apparatus according to claim 1, wherein
the tray is made of an aluminum alloy.

16. The substrate transfer apparatus according to claim 1, wherein
the tray has a thickness of 0.5 mm to 2.0 mm.
